(19) United States
(12) Patent Application Publication
(10) Pub. No.: US 2026/0006888 A1
(43) Pub. Date: Jan. 1, 2026

(54) SELECTIVE PROCESS FOR SIMULTANEOUS PFET EPI HARDMASK AND NFET PARTIAL BOTTOM DIELECTRIC ISOLATION LAYER FORMATION

(71) Applicant: Applied Materials, Inc., Santa Clara, CA (US)

(72) Inventors: Veeraraghavan S. BASKER, Schenectady, NY (US); Benjamin COLOMBEAU, San Jose, CA (US); Balasubramanian PRANATHARTHIHARAN, Santa Clara, CA (US)

(21) Appl. No.: 19/221,459

(22) Filed: May 28, 2025

Related U.S. Application Data
(60) Provisional application No. 63/664,589, filed on Jun. 26, 2024.

(51) Int. Cl. H10D 84/01; H01L 21/02; H01L 21/67; H10D 30/00; H10D 30/01; H10D 30/43; H10D 62/10; H10D 62/13; H10D 84/85

(52) U.S. Cl. CPC H10D 84/017; H01L 21/02247; H01L 21/02252; H01L 21/02329; H01L 21/0234; H01L 21/67207; H10D 30/014; H10D 30/019; H10D 84/0188; H10D 30/43; H10D 30/502; H10D 62/121; H10D 62/151; H10D 84/851

(57) ABSTRACT

Embodiments described herein generally relate to methods of forming hardmask and bottom dielectric isolation layers in vertical trench structures. A method of forming a gate-all-around field-effect transistor includes depositing a conformal oxide layer on a channel surface and a bottom surface of vertical structures of a substrate, the vertical structures including an NMOS portion having NMOS vertical structures defining NMOS contact trenches and a PMOS portion having PMOS structures defining PMOS contact trenches having a PMOS source/drain layer deposited therein. The method further includes selectively etching the conformal oxide layer at the bottom surface of the vertical structures, inhibiting the conformal oxide layer, selectively depositing a nitride layer at the bottom surface of the vertical structures, etching the conformal oxide layer to expose the channel surface of the vertical structures, and depositing an NMOS source/drain layer on the bottom surface of the NMOS contact trenches.

### CROSS REFERENCE TO RELATED APPLICATIONS

This application claims priority to U.S. Provisional Application Ser. No. 63/664,589 filed Jun. 26, 2024, which is herein incorporated by reference in its entirety.

### BACKGROUND

### Field

Embodiments described herein generally relate to semiconductor device fabrication, and more particularly, to methods of forming hardmask layers and bottom dielectric isolation layers in vertical trench structures.

### Description of the Related Art

The production of silicon integrated circuits, including Gate-All-Around (GAA) field-effect transistors, has placed difficult demands on fabrication processes to increase the number of devices while decreasing the minimum feature sizes on a chip. These demands have extended to fabrication processes including depositing layers onto difficult topologies while maintaining device reliability. For example, a vertical trench structure used in 4F² (feature square) dynamic random access memory (DRAM) devices may include thin silicon channel pillars having a thickness of less than about 10 nm.

To produce these structures, continuous deposition and removal of hardmask is needed to form a source/drain (S/D) epitaxial (epi) layer. The hardmask are used to prevent deposition on n-type metal-oxide-semiconductor field-effect transistor (NFET) channel pillars when a p-type metal-oxide-semiconductor field-effect transistor (PFET) S/D epi layer is grown and vice-versa. However, due to limited space between the channel pillars, each hardmask has to be removed after each instance of epitaxial growth to prevent pinching off in the channels between the channel pillars. The repeated deposition and removal of hardmask during complimentary metal-oxide-semiconductor (CMOS) manufacturing complicates the S/D module integration.

Accordingly, there is a need for improved processes for forming the source/drain epi layers of a CMOS structure for GAA architecture.

### SUMMARY

Embodiments described herein generally relate to semiconductor device fabrication, and more particularly, to methods of forming hardmask layers and bottom dielectric isolation layers in vertical trench structures.

In an embodiment, a method of forming a portion of a gate-all-around field-effect transistor (GAA FET) is provided. The method includes depositing a conformal oxide layer on a channel surface and a bottom surface of vertical structures of a substrate, the vertical structures including an N-channel metal-oxide semiconductor (NMOS) portion having NMOS vertical structures defining NMOS contact trenches and a P-channel metal-oxide semiconductor (PMOS) portion having PMOS structures defining PMOS contact trenches having a PMOS source/drain layer deposited therein. The method further includes selectively etching the conformal oxide layer at the bottom surface of the vertical structures, inhibiting the conformal oxide layer, selectively depositing a nitride layer at the bottom surface of the vertical structures, etching the conformal oxide layer to expose the channel surface of the vertical structures, and depositing an NMOS source/drain layer on the bottom surface of the NMOS contact trenches.

In another embodiment, a method of forming a portion of a gate-all-around field-effect transistor (GAA FET) is provided. The method includes depositing a conformal oxide layer on a channel surface and a bottom surface of vertical structures of a substrate in a first processing chamber, the vertical structures including NMOS vertical structures formed on an NMOS portion of the substrate and PMOS vertical structures formed on a PMOS portion of the substrate, the NMOS vertical structures defining NMOS contact trenches and the PMOS structures defining PMOS contact trenches having a PMOS source/drain layer deposited therein. The method also includes selectively etching the conformal oxide layer at the bottom surface of the vertical structures in a second processing chamber, selectively depositing a nitride layer at the bottom surface of the vertical structures in a third processing chamber, etching the conformal oxide layer to expose the channel surface of the vertical structures in the second processing chamber, and depositing an NMOS source/drain layer on the bottom surface of the vertical structures in the first processing chamber.

In yet another embodiment, a multi-chamber cluster tool is provided. The multi-chamber cluster tool includes a first processing chamber, a second processing chamber, a third processing chamber, and a controller. The controller is configured to cause the multi-chamber cluster tool to, after deposition of a PMOS source/drain layers in PMOS contact trenches of a substrate, deposit a conformal oxide layer on vertical trench surfaces and bottom surfaces of vertical trenches defined by vertical structures of the substrate in the first processing chamber, the substrate having an NMOS portion having NMOS vertical structures defining NMOS contact trenches and a PMOS portion having PMOS vertical structures defining the PMOS contact trenches having the PMOS source/drain layers deposited therein. The controller is further configured to selectively inhibit the oxide layer in the first processing chamber, selectively deposit a nitride layer at the bottom surfaces of the vertical structures in the second processing chamber, and deposit an NMOS source/drain layer on the NMOS bottom surface the NMOS channels in the first processing chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the present disclosure and are therefore not to be considered limiting of its scope, and the present disclosure may admit to other equally effective embodiments.

FIG. 1 is a schematic view of a multi-chamber cluster tool, according to certain embodiments.

FIG. 2 illustrates a flow diagram of a method of processing a substrate, according to certain embodiments.

FIGS. 3A, 3B, 3C, 3D, 3E, 3F, 3G, and 3H illustrate a substrate undergoing the method of FIG. 2, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to semiconductor device fabrication, and more particularly, to methods of forming hardmask layers and bottom dielectric isolation layers in vertical trench structures.

Gate-All-Around (GAA) field-effect transistors (GAA FETs) are considered a potential replacement for fin field-effect transistors (FinFETs). In a GAA FET, the gate material surrounds the silicon semiconductor channel on all four sides, unlike current FinFET devices where it covers the channel from three sides. This design enables better control of the current flow in the channel, reducing the supply voltage level and enhancing performance by boosting drive current capability.

In certain GAA devices like GAA nanosheet FETs, alternating layers of silicon and silicon germanium (SiGe) are patterned into pillars, with an indentation in the SiGe layers to accommodate an inner spacer between the source/drain. This spacer is eventually deposited next to the pillar and the space where the gate will be.

Hard masks are used in forming the NFET and PFET structures for GAA transistors to define the shape and size of structures etched on the semiconductor substrate during lithography. Bottom Dielectric Isolation (BDI) layers are used to isolate the stack from the substrate, reducing leakage and enabling precise gate lengths. The BDI layer facilitates the formation of nanosheets and isolates the gate from the source and drain in GAA nanosheet FETs.

In current complimentary metal-oxide-semiconductor (CMOS) structure processing, however, continuous deposition and removal of hardmask layers is needed to form source/drain (S/D) epitaxial (epi) layers. For example, hardmask layers are used to cover NFET fins or vertical structures when PFET epitaxially grown S/D epi layers are grown and vice-versa. However, there is very little canyon space available between the vertical structures, requiring hardmask layers to be removed after each instance to prevent the canyon space from getting pinched off. This greatly impacts the gate spacer and complicates the S/D module integration.

The present disclosure provide for systems and methods of simultaneously forming selective hardmask on PFET S/D epi layers and partial BDI layers at the bottom of each NFET channel at the NFET S/D region. The methods of the present disclosure include depositing a conformal oxide layer onto the PFET and NFET vertical structures, etching the conformal oxide layer at the bottom of the channels between each of the vertical structures, depositing a nitride layer at the bottom of the channels, densifying the nitride layer, then removing the remaining portion of the conformal oxide layer from the PFET and NFET vertical structures before depositing NFET S/D epi layers into the NFET channels. The methods of the present disclosure reduce the frequency with which hardmask layers need to be removed during CMOS processing.

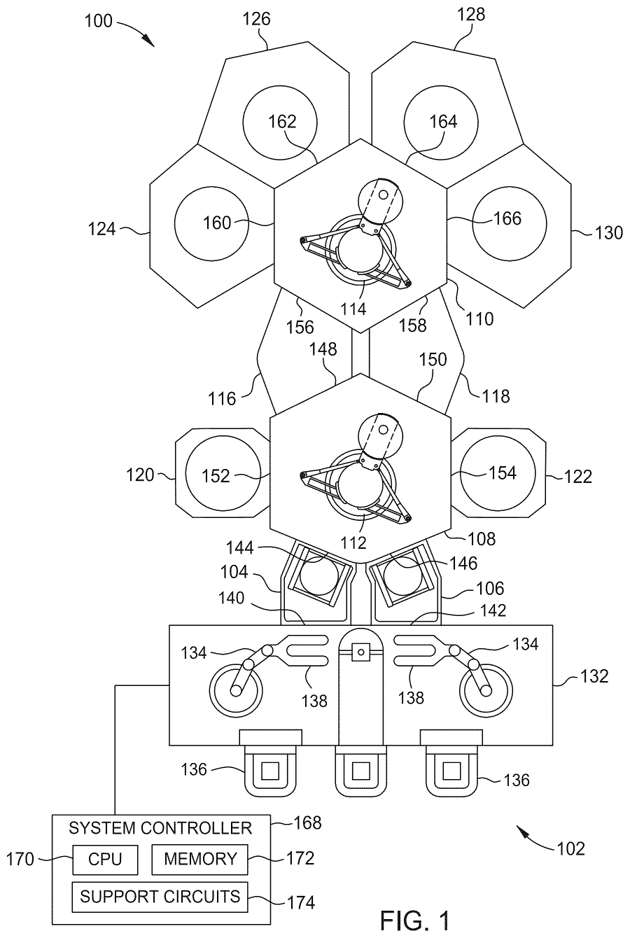

FIG. 1 is a schematic top view of a multi-chamber cluster tool 100, according to one or more embodiments of the present disclosure. The multi-chamber cluster tool 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the multi-chamber cluster tool 100 can be processed in and transferred between the various chambers without exposing the substrates to an ambient environment exterior to the multi-chamber cluster tool 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the multi-chamber cluster tool 100. Accordingly, the multi-chamber cluster tool 100 may provide for an integrated solution for some processing of substrates.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, and 130. The ports 144, 146, 148, 150, 152, 154, 156, 158, 160, 162, 164, and 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, or roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

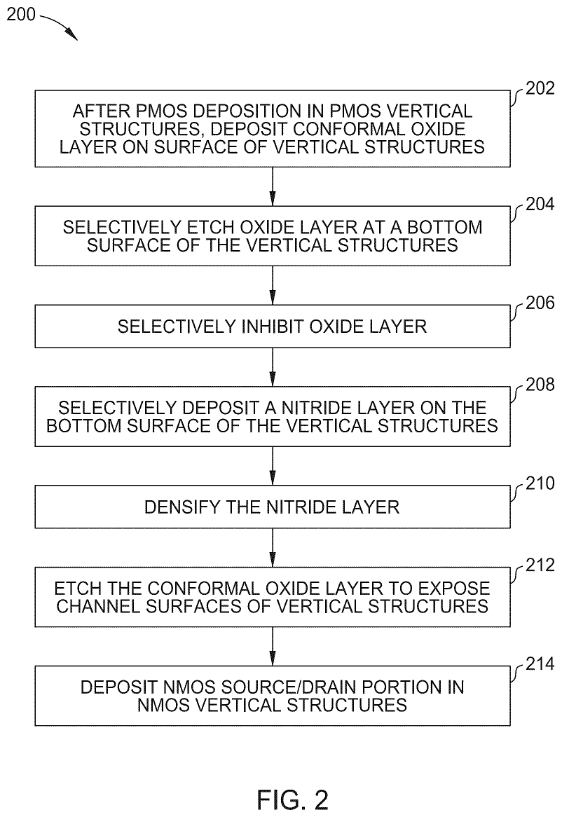

The processing chambers 120, 122, 124, 126, 128, 130 can be any appropriate chamber for processing a substrate. In some examples, the processing chamber 120 can be capable of performing an etch process, the processing chamber 122 can be capable of performing a cleaning process, and the processing chambers 126, 128, 130 can be capable of performing respective epitaxial growth processes. The processing chamber 120 may be an etching chamber. The processing chamber 122 may be a pre-clean chamber. The processing chamber 124, 126, 128, or 130 may be a deposition chamber, such as an epitaxial deposition chamber, a CVD/ALD chamber, a physical vapor deposition (PVD) chamber, a selective tungsten deposition chamber, an ionized metal plasma physical vapor deposition (IMP PVD) chamber, a rapid thermal process (RTP) chamber, or a plasma etch (PE) chamber. A system controller 168 is coupled to the multi-chamber cluster tool 100 for controlling the multi-chamber cluster tool 100 or components thereof. For example, the system controller 168 may control the operation of the multi-chamber cluster tool 100 using a direct control of the chambers 104, 106, 108, 110, 116, 118, and the processing chambers 120, 122, 124, 126, 128, 130 of the multi-chamber cluster tool 100 or by controlling controllers associated with the chambers 104, 106, 108, 110, 116, 118, and the processing chambers 120, 122, 124, 126, 128, 130. In operation, the system controller 168 enables data collection and feedback from the respective chambers to coordinate performance of the multi-chamber cluster tool 100. The system controller 168 is configured to cause the chambers 104, 106, 108, 110, 116, 118, and the processing chambers 120, 122, 124, 126, 128, 130 of the multi-chamber cluster tool 100 to perform all of the operations described with respect to the method of FIG. 2.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

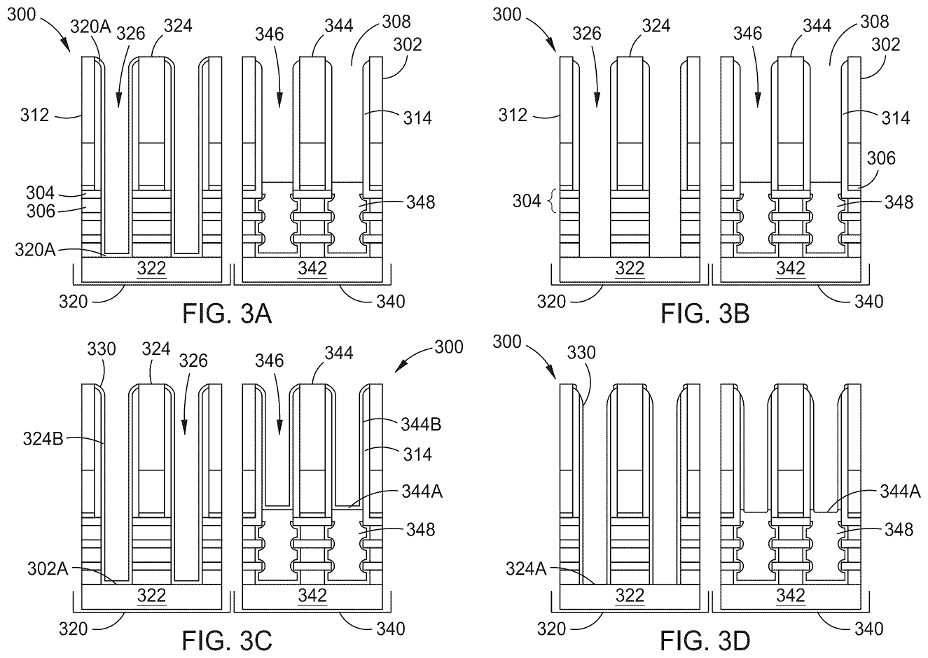

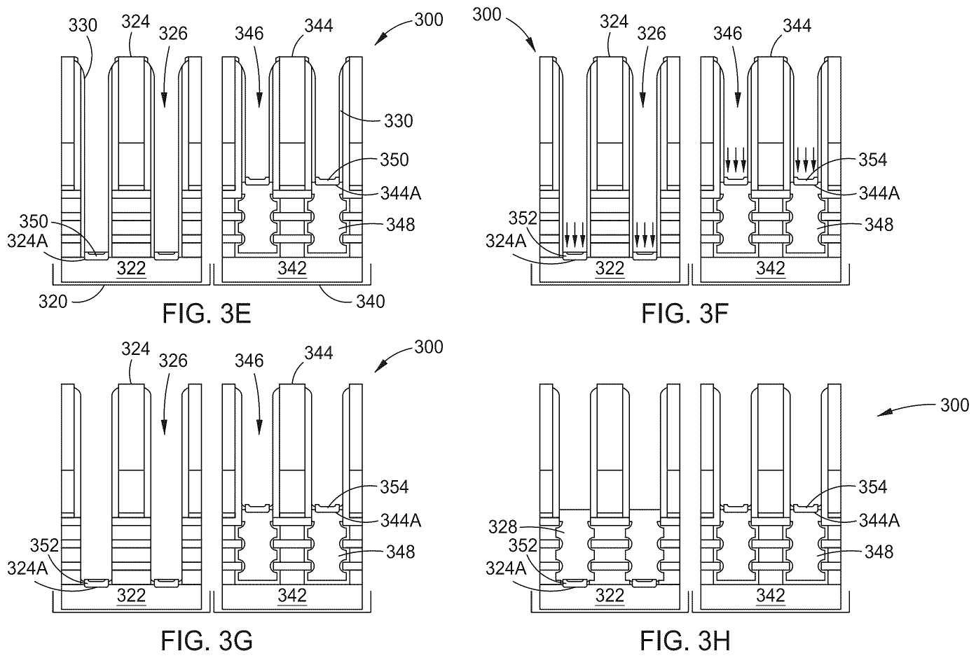

FIG. 2 illustrates a flow diagram of a method 200 of forming a hardmask layer and a bottom dielectric isolation (BDI) layer in a vertical structure, according to certain embodiments. FIGS. 3A-3H illustrate schematic, cross-sectional views of a portion of a semiconductor structure 300 with a plurality of vertical structures 302 undergoing the method 200 of FIG. 2, according to certain embodiments. The semiconductor structure 300 may form a gate-all-around field-effect transistor (GAA FET), according to one or more embodiments of the present structure.

As shown in FIG. 3A, the semiconductor structure 300 includes the vertical structures 302 defining vertical trenches 308 having a bottom surface 302A and vertical trench surfaces 314 and formed on an N-channel metal-oxide semiconductor (NMOS) portion 320 and a P-channel metal-oxide semiconductor (PMOS) portion 340. The vertical structures 302 include channel layers 304 and a replacement-metal-gate (RMG) stack 306 having layers of a gate metal and a dielectric material. The channel layers 304 may be formed of silicon (Si), germanium (Ge), silicon germanium (SiGe), or indium gallium zinc oxide (IGZO). Surfaces of the RMG stacks 306 may be covered by spacers (not shown). The spacers may be formed of dielectric material, such as silicon oxide (SiO₂), silicon oxy-carbide (SiOC), silicon oxy-carbon-nitride (SiOCN), silicon boron carbon nitride (SiBCN), or silicon nitride (Si₃N₄). The gate metal gate metal may be formed of titanium nitride (TiN), or titanium aluminum carbide (TiAlC), or tungsten (W). The dielectric material may be formed of hafnium oxides (HfO₂), hafnium zirconium oxide (HfZrO₂), or aluminum oxide (Al₂O₃).

The vertical structures 302 also include a gate hardmask 312 disposed on the channel layers 304. The NMOS portion 320 includes a NMOS substrate layer 322 with vertical structures, e.g., NMOS vertical structures 324, formed thereon. The NMOS vertical structures 324 define a plurality of NMOS contact trenches 326. Similarly, the PMOS portion 340 includes a PMOS substrate layer 342 with vertical structures, e.g., PMOS vertical structures 344, formed thereon. The PMOS vertical structures 344 define a plurality of PMOS contact trenches 346. The semiconductor structure 300 is shown in FIG. 3A after a PMOS epitaxial growth process to deposit a PMOS source/drain epi layer 348 in the PMOS contact trench 346 of the PMOS portion 340. For example, as shown in FIG. 3A, a hard mask 320A may be deposited over the NMOS vertical structures 324 and patterned. The PMOS source/drain epi layer 348 is then deposited in the PMOS contact trenches 346, e.g., via epitaxial growth processes. The hard mask 320A over the NMOS vertical structures 324 prevents epi growth in the NMOS portion 320 and, in particular, in the NMOS contact trenches 326. Thus, the PMOS source/drain epi layer 348 is deposited only in the PMOS contact trenches 346 while the NMOS contact trenches 326 do not have a source/drain epi layer disposed therein. After the PMOS source/drain epi layer is deposited, the hard mask may be removed, e.g., stripped, from the surfaces of the NMOS portion 320 as shown in FIG. 3B. The PMOS source/drain epi layer 348 electrically connects the channel layers 304 to an S/D contact (not shown) via an extension region (not shown).

The S/D contact may be formed of tungsten (W), ruthenium (Ru), molybdenum (Mo), copper (Cu), cobalt (Co), titanium (Ti), nickel (Ni), silver (Ag), gold (Au), iridium (Ir), tantalum (Ta), platinum (Pt), conductive oxides or nitrides thereof, or any combination thereof.

The PMOS source/drain epi layer 348 may be formed of epitaxially grown silicon germanium (SiGe) with a ratio of germanium (Ge) ranging between 10% and 65%, doped with p-type dopants such as boron (B) or gallium (Ga), with a concentration of between about 10¹⁸ cm⁻³ and 5×·10²¹ cm⁻³.

In operation 202 of method 200, a conformal oxide layer 330 is deposited on the surface of the semiconductor structure 300, as shown in FIG. 3C. The conformal oxide layer 330 is deposited on an NMOS bottom surface 324A at an interface of the NMOS contact trench 326 and the NMOS substrate layer 322. The conformal oxide layer 330 is also deposited on an NMOS channel surface 324B of the NMOS contact trench 326 and the NMOS vertical structures 324 of the NMOS portion 320. The conformal oxide layer 330 is simultaneously deposited at a PMOS bottom surface 344A at the interface of the PMOS contact trench 346 and the PMOS source/drain epi layer 348. The conformal oxide layer 330 is also deposited on a PMOS channel surface 344B of the PMOS contact trench 346 and the PMOS vertical structures 344 of the PMOS portion 340. The NMOS bottom surface 324A of each NMOS contact trench 326 is located at a top surface of the NMOS substrate layer 322. After operation 202, the conformal oxide layer 330 is in direct contact with the NMOS substrate layer 322 at the NMOS bottom surface 324A of each NMOS contact trench 326. The PMOS vertical structures 344 of each PMOS contact trench 346 is located at a top surface of the PMOS source/drain epi layer 348 in each PMOS contact trench 346. After operation 202, the conformal oxide layer 330 is in direct contact with the PMOS source/drain epi layer 348 at the PMOS bottom surface 344A of each PMOS contact trench 346.

The conformal oxide layer 330 may be deposited in a first processing chamber, e.g., the processing chambers 126, 128, and 130, by oxidizing a conformal silicon layer or by directly depositing a silicon oxide layer. For example, a silicon layer formation process may be used to form a thin silicon layer on the exposed surfaces of the vertical structures 302 and the exposed surfaces of the underlying substrate, such as at the NMOS bottom surface 324A. The thin silicon layer may be an epitaxial layer of silicon (Si) formed by a selective epitaxial deposition process performed in a processing chamber, such as the processing chamber 126, 128, or 130 shown in FIG. 1.

The selective epitaxial deposition process may include a conformal epitaxial deposition process and an etch process. For example, in an epitaxial deposition process in which the vertical structures 302 are exposed to a deposition gas, an amorphous layer of silicon (Si) may be formed on the bottom surface 302A of the vertical structures 302 and an epitaxial layer of silicon (Si) may be formed on the vertical trench surface 314 of the vertical structures 302, e.g., the 324B and the 344B. In a subsequent etch process, the amorphous layer can be etched at a faster rate than the epitaxial layer, by an appropriate etching gas. Thus, an overall result of the epitaxial deposition process and the etch process combined can be a selective epitaxial growth on the vertical trench surfaces 314 of the vertical structures 302, while minimizing growth, if any, on the bottom surface 302A.

In some embodiments, the deposition gas includes a silicon-containing precursor, a carrier gas, and an optional dopant source. The silicon-containing precursor may include silane (SiH₄), disilane (Si₂H₆), dichlorosilane (SiH₂Cl₂), tetrasilane (Si₄H₁₀), or a combination thereof. In the selective epitaxial deposition process, the etching gas includes an etchant gas and a carrier gas. The etchant gas may include halogen-containing gas, such as hydrogen chloride (HCl), chlorine (Cl₂), or hydrogen fluoride (HF). The carrier gas may include nitrogen (N₂), argon (Ar), helium (He), hydrogen (H₂), or nitrogen (N₂). Optional dopant source can be n-type, e.g. phosphine (PH3) and arsine (AsH₃), or p-type, e.g. diborane (B₂H₆) and boron trichloride (BCl₃).

The epitaxial deposition process may be performed at a low temperature less than about 450° C. and at a pressure of between about 5 Torr and about 600 Torr, or at a high temperature at about 700° C. and a pressure of below about 600 Torr. A cycle of the epitaxial deposition and etch processes may be repeated as needed to obtain a desired thickness of the conformal oxide layer 330.

Alternatively, a silicon layer used to create the conformal oxide layer 330 is formed by an interface formation process and a conformal deposition process. For example, the interface formation process may form an interfacial layer of amorphous silicon oxide (SiO₂) on the vertical trench surface 314 of the vertical structures 302 and the NMOS bottom surface 324A. The conformal deposition process deposits a silicon layer of the interfacial layer.

The interface formation process may include a suitable thermal oxidation process, such as an enhanced in-situ steam generation (eISSG) process utilizing nitrous oxide (N₂O) gas, a radical oxidation process utilizing hydrogen (H₂) and oxygen (O₂) gases, or a rapid thermal oxidation (RTO) process utilizing oxygen (O₂) gas, performed in the first chamber, e.g., the processing chambers 126, 128, or 130 shown in FIG. 1. The interfacial layer may act as a nucleation layer of a silicon layer to be deposited thereon and improve quality (e.g., such as interface state density, accumulation capacitance, frequency dispersion, and leakage current) of the interface between the substrate, e.g., at the NMOS bottom surface 324A, and the conformal oxide layer 330 to be formed.

The deposition process may be any appropriate deposition process, such as atomic layer deposition (ALD), epitaxial deposition, chemical vapor deposition (CVD), physical vapor deposition (PVD), or the like performed in the first processing chamber, such as the processing chambers 126, 128, or 130 shown in FIG. 1.

Once the conformal silicon layer is formed, a thermal oxidation process may be performed, in which the silicon layer is oxidized to convert the silicon layer to a conformal oxide layer 330, as shown in FIG. 3B. The conformal oxide layer 330 may be formed of silicon dioxide (SiO₂).

The thermal oxidation process may include a radical oxidation process utilizing H₂ and O₂ gases, or a rapid thermal oxidation (RTO) process utilizing O₂ gas. The thermal oxidation process may be performed in a processing chamber, such as the processing chamber 126, 128, or 130 shown in FIG. 1. The thermal oxidation process may not change a thickness of the silicon layer, and thus the conformal oxide layer 330 may have a similar thickness.

In some embodiments, alternative to the thermal oxidation process, a silicon oxide (SiO₂) layer is deposited on the silicon layer formed in the silicon layer formation process, with or without an interfacial layer of amorphous silicon oxide (SiO₂), and densified into the conformal oxide layer 330. The deposition process to deposit a silicon oxide (SiO₂) layer may be any appropriate deposition process, such as atomic layer deposition (ALD), chemical vapor deposition (CVD), or the like performed in a processing chamber, such as the processing chamber 126, 128, or 130 shown in FIG. 1. The densification of the silicon oxide (SiO₂) layer is performed by a plasma treatment, such as a decoupled plasma (DPHe) process and a remote plasma oxidation (RPO2) process.

In operation 204, the conformal oxide layer 330 is selectively etched such that portions of the conformal oxide layer 330 are removed at the NMOS bottom surface 324A of the NMOS portion 320 and the PMOS bottom surface 344A of the PMOS portion 340, exposing the NMOS substrate layer 322 at the NMOS portion 320 and the PMOS source/drain epi layer 348 at the PMOS portion 340, as shown in FIG. 3C. The conformal oxide layer 330 may be selectively etched using any suitable etching methods in a second processing chamber, e.g., the processing chamber 120. For example, the conformal oxide layer 330 may be etched using an anisotropic etch process, such as reactive ion etching (RIE) as RIE is directional, allowing the portions of the conformal oxide layer 330 at the NMOS bottom surface 324A and the PMOS bottom surface 344A to be etched while keeping the remaining portion of the conformal oxide layer 330 intact.

The conformal oxide layer 330 may be inhibited using an inhibition process in the first processing chamber, e.g., the processing chambers 126, 128, or 130, in operation 206. For example, the conformal oxide layer 330 may be passivated. In this embodiment, the exposed surfaces of the conformal oxide layer 330, e.g., the conformal oxide layer 330 disposed on the vertical trench surface 314, are —OH terminated. A silyl amine precursor, such as 1 (trimethylsilyl) pyrrolidine, or an aminosilane, including aminosilane and diaminosilane, and dichlorodimethylsilane, may be reacted with the —OH terminated conformal oxide layer 330. In certain embodiments, the precursors may be reacted together with the —OH terminated surface or sequentially with the —OH terminated surface. In one embodiment, the precursor may be thermally dissociated at a temperature of less than about 500° C., such as less than about 400° C. The passivation process may be performed at a pressure of between about 3 Torr and about 30 Torr for a time of between about 5 seconds and about 50 seconds, for example, between about 10 second and about 30 seconds, for example, about 20 seconds. The processing conditions may facilitate alkyl silyl termination of the exposed surface. Additional reaction products, such as pyrrolidine and ammonia, may be evacuated from the processing volume.

Then, in operation 208, a nitride layer 350 is deposited at the NMOS bottom surface 324A of the NMOS portion 320 and the PMOS bottom surface 344A of the PMOS portion 340, as shown in FIG. 3D. A directional nitridation process is performed to form the nitride layer 350. The directional nitridation process may be a plasma treatment process, such as a decoupled plasma nitridation (DPN) process, a decoupled plasma (DPX) process, a decoupled plasma plus (DPX+) process, or a rapid thermal nitridation (RTN) process performed in a third processing chamber, such as the processing chambers 126, 128, and 130 shown in FIG. 1. The conformal oxide layer 330 prevents deposition of the nitride layer 350 on surfaces other than the NMOS bottom surface 324A and the PMOS bottom surface 344A. The nitride layer 350 may be made of suitable hardmask and BDI materials. For example, the nitride layer 350 may be formed of silicon nitride (Si₃N₄). Gases that may be used in the plasma treatment process include a nitrogen containing gas, such as nitrogen (N₂), ammonia (NH₃), or mixtures thereof.

As shown in FIG. 3E, the nitride layer 350 undergoes a densification process in operation 210. For example, the nitride layer 350 may be densified by a plasma nitridation process that is performed to insert nitrogen atoms into vacancies and defects in the nitride layer 350. The plasma nitridation process may be a plasma treatment process, such as decoupled plasma nitridation (DPN) process, a decoupled plasma (DPX) process, a decoupled plasma plus (DPX+) process, or a rapid thermal nitridation (RTN) process performed in the third processing chamber, such as the processing chambers 126, 128, and 130 shown in FIG. 1. The plasma nitridation process exposes the nitride layer 350 to additional nitrogen plasma, which may allow nitrogen radicals or nitrogen atoms to be incorporated within the nitride layer 350, on the top surface, throughout the thickness, or at the interface of the nitride layer 350. Gases that may be used in the plasma treatment process include nitrogen containing gas, such as nitrogen (N₂), ammonia (NH₃), or mixtures thereof.

The plasma nitridation process may include an optional thermal nitridation process performed to stabilize nitrogen atoms into vacancies and defects in the nitride layer 350. The thermal nitridation process may include a thermal anneal process, performed in a rapid thermal processing (RTP) chamber, which may be any of the processing chambers 120, 122, 124, 126, 128, and 130 shown in FIG. 1.

The densification of the nitride layer 350 improves the quality of the nitride layer 350 and forms BDI portions 352 of the nitride layer 350 in the NMOS bottom surface 324A that act as a BDI layer, preserving the NMOS substrate layer 322 of the NMOS portion 320. The densified portions of the nitride layer 350 in the PMOS bottom surface 344A form hardmask portions 354 which act as hardmask layers, preserving the PMOS source/drain epi layer 348 during NMOS epitaxial growth.

As shown in FIG. 3F, the conformal oxide layer 330 is etched or otherwise removed from the semiconductor structure 300, including the NMOS portion 320 and the PMOS portion 340, in the second processing chamber, e.g., the processing chamber 120, in operation 212. For example, the etching process to remove the conformal oxide layer 330 may include an isotropic plasma etch process, such as a dry chemical etch process, using amorphous hydrofluoric acid (HF) and ammonia (NH₃), or a remote-plasma-assisted dry etch process using a plasma formed from a gas including ammonia (NH₃) or nitrogen trifluoride (NF₃), or a wet etch process. The dry etch process is selective for oxide layers, and thus does not readily etch silicon, germanium, or nitride layers regardless of whether the layers are amorphous, crystalline or polycrystalline.

A NMOS source/drain epi layer 328 is then deposited or grown in each of the NMOS contact trench 326 over the BDI portions 352 at the NMOS bottom surface 324A in operation 214 as shown in FIG. 3G. The NMOS source/drain epi layer 328 may be formed of epitaxially grown silicon (Si), doped with n-type dopants, such as phosphorus (P), arsenic (As), or antimony (Sb), with a concentration of between about 1020 cm⁻³ and 5×·10²¹ cm⁻³.

The present disclosure provide for systems and methods of forming selective hardmask layers on PFET epitaxially-grown source/drain (S/D) layers while simultaneously depositing a partial BDI layer at the bottom of NFET S/D region. The simultaneous deposition of the hardmask layers and the BDI layer as described, reduces the frequency with which hardmask layers need to be removed during CMOS processing while also preserving the performance of the CMOS device.

When introducing elements of the present disclosure or exemplary aspects or embodiments thereof, the articles “a,” “an,” “the” and “said” are intended to mean that there are one or more of the elements.

The terms “comprising,” “including” and “having” are intended to be inclusive and mean that there may be additional elements other than the listed elements.

The term “coupled” is used herein to refer to the direct or indirect coupling between two objects. For example, if object A physically touches object B and object B touches object C, the objects A and C may still be considered coupled to one another-even if objects A and C do not directly physically touch each other. For instance, a first object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A method of forming a portion of a gate-all-around field-effect transistor (GAA FET), comprising:
depositing a conformal oxide layer on a channel surface and a bottom surface of vertical structures of a substrate, the vertical structures comprising an N-channel metal-oxide semiconductor (NMOS) portion having NMOS vertical structures defining NMOS contact trenches and a P-channel metal-oxide semiconductor (PMOS) portion having PMOS structures defining PMOS contact trenches having a PMOS source/drain layer deposited therein;
selectively etching the conformal oxide layer at the bottom surface of the vertical structures;
inhibiting the conformal oxide layer;
selectively depositing a nitride layer at the bottom surface of the vertical structures;
etching the conformal oxide layer to expose the channel surface of the vertical structures; and
depositing an NMOS source/drain layer on the bottom surface of the NMOS contact trenches.

2. The method of claim 1, further comprising:
before depositing the conformal oxide layer:
depositing a hard mask layer on the NMOS portion;
depositing the PMOS source/drain layer in the PMOS contact trenches; and
removing the hard mask layer from the NMOS portion after depositing the PMOS source/drain layer.

3. The method of claim 1, further comprising:
before depositing the NMOS source/drain layer, densifying the nitride layer.

4. The method of claim 3, wherein densifying the nitride layer includes inserting nitrogen atoms into the nitride layer using a plasma treatment process.

5. The method of claim 4, wherein the plasma treatment process is a decoupled plasma nitridation process, a decoupled plasma process, a decoupled plasma plus process, or a rapid thermal nitridation process.

6. The method of claim 1, wherein the selectively depositing the nitride layer includes performing a directional nitridation process to deposit the nitride layer.

7. The method of claim 6, wherein the directional nitridation process includes a decoupled plasma nitridation process, a decoupled plasma process, a decoupled plasma plus process, or a rapid thermal nitridation process.

8. The method of claim 1, wherein the nitride layer forms bottom dielectric isolation portions at the bottom surface of the NMOS contact trenches.

9. The method of claim 1, wherein the nitride layer is deposited on PMOS source/drain layers in the PMOS contact trenches.

10. The method of claim 9, wherein the nitride layer forms hardmask portions at the bottom surface of the PMOS contact trenches.

11. A method of forming a portion of a gate-all-around field-effect transistor (GAA FET) in a multi-chamber cluster tool, comprising:
depositing a conformal oxide layer on a channel surface and a bottom surface of vertical structures of a substrate in a first processing chamber, the vertical structures comprising NMOS vertical structures formed on an NMOS portion of the substrate and PMOS vertical structures formed on a PMOS portion of the substrate, the NMOS vertical structures defining NMOS contact trenches and the PMOS structures defining PMOS contact trenches having a PMOS source/drain layer deposited therein;
selectively etching the conformal oxide layer at the bottom surface of the vertical structures in a second processing chamber;
selectively depositing a nitride layer at the bottom surface of the vertical structures in a third processing chamber;
etching the conformal oxide layer to expose the channel surface of the vertical structures in the second processing chamber; and
depositing an NMOS source/drain layer on the bottom surface of the vertical structures in the first processing chamber.

12. The method of claim 11, further comprising:
before etching the conformal oxide layer, densify the nitride layer to form bottom dielectric isolation portions in the NMOS channels and hardmask portions in the PMOS channels in the third processing chamber.

13. The method of claim 11, further comprising:
after etching the conformal oxide layer, densify the nitride layer to form BDI portions in the NMOS channels and hardmask portions in the PMOS channels in the third processing chamber.

14. The method of claim 11, further comprising:
before selectively depositing the nitride layer and after selectively etching the conformal oxide layer, selectively inhibiting the conformal oxide layer in the first processing chamber.

15. A multi-chamber cluster tool, comprising:
a first processing chamber;
a second processing chamber; and
a controller configured to cause the multi-chamber cluster tool to:
after deposition of a PMOS source/drain layers in PMOS contact trenches of a substrate, deposit a conformal oxide layer on vertical trench surfaces and bottom surfaces of vertical trenches defined by vertical structures of the substrate in the first processing chamber, the substrate having an NMOS portion having NMOS vertical structures defining NMOS contact trenches and a PMOS portion having PMOS vertical structures defining the PMOS contact trenches having the PMOS source/drain layers deposited therein;
selectively inhibit the oxide layer in the first processing chamber;
selectively deposit a nitride layer at the bottom surfaces of the vertical structures in the second processing chamber; and
deposit an NMOS source/drain layer on the NMOS bottom surface the NMOS channels in the first processing chamber.

16. The multi-chamber cluster tool of claim 15, wherein the NMOS contact trenches comprise an NMOS bottom surface at an interface with an NMOS substrate layer disposed between the NMOS vertical structures, the nitride layer deposited on the NMOS bottom surface of the NMOS contact trenches.

17. The multi-chamber cluster tool of claim 15, wherein the PMOS contact trenches comprise a PMOS bottom surface at an interface with the PMOS source/drain layers disposed in the PMOS contact trenches, the nitride layer deposited on the PMOS bottom surface of the PMOS channels.

18. The multi-chamber cluster tool of claim 15, wherein the controller is further configured to:
densify the nitride layer in the second processing chamber.

19. The multi-chamber cluster tool of claim 15, wherein the nitride layer deposited on the NMOS bottom surface forms bottom dielectric isolation portions configured to preserve an NMOS layer beneath the NMOS vertical structures.

20. The multi-chamber cluster tool of claim 15, wherein the nitride layer deposited on the PMOS bottom surface forms hardmask portions configured to preserve the PMOS source/drain layers in the PMOS channels.
